(19) United States
(12) Patent Application Publication
(10) Pub. No.: US 2023/0007832 A1
(43) Pub. Date: Jan. 12, 2023

(54) SEMICONDUCTOR STRUCTURE AND METHOD FOR FABRICATING SEMICONDUCTOR STRUCTURE

(71) Applicant: CHANGXIN MEMORY TECHNOLOGIES, INC., Hefei (CN)

(72) Inventor: Yutong SHEN, Hefei (CN)

(21) Appl. No.: 17/509,073

(22) Filed: Oct. 25, 2021

Related U.S. Application Data
(63) Continuation of application No. PCT/CN2021/117527, filed on Sep. 9, 2021.

(30) Foreign Application Priority Data
Jul. 9, 2021 (CN) 202110778396.2

(51) Int. Cl. H01L 29/778; H01L 29/20; H01L 29/66

(52) U.S. Cl. CPC H01L 29/7786; H01L 29/2003; H01L 29/66462

(57) ABSTRACT

Embodiments relate to the field of semiconductor technology, and propose a semiconductor structure and a method for fabricating a semiconductor structure. The semiconductor structure includes: a channel layer including a group III-V semiconductor and a group III-V semiconductor layer, the group III-V semiconductor and the group III-V semiconductor layer forming a heterojunction; a gate structure positioned on the channel layer, the gate structure including a gallium oxide layer, a gate oxide layer, and a gate electrode stacked in sequence; a source electrode positioned at an end of the heterojunction; and a drain electrode positioned at other end of the heterojunction.

### CROSS-REFERENCE TO RELATED APPLICATION

The present disclosure is a continuation of PCT/CN2021/117527, filed on Sep. 9, 2021, which claims priority to Chinese Patent Application No. 202110778396.2, titled “SEMICONDUCTOR STRUCTURE AND METHOD FOR FABRICATING SEMICONDUCTOR STRUCTURE” and filed on Jul. 9, 2021, the entire contents of which are incorporated herein by reference.

### TECHNICAL FIELD

The present disclosure relates to the field of semiconductor technology, and more particularly, to a semiconductor structure and a method for fabricating a semiconductor structure.

### BACKGROUND

In the field of fabrication of dynamic random access memory (DRAM), as requirements for storing and reading data are getting higher and higher, in traditional silicon-based transistor structures, source and drain regions are doped with high-concentration ions that are opposite in type to ions doped on substrates. In this way, ON or OFF of transistors is implemented by controlling accumulation or depletion of majority carriers on surfaces of the substrates after a working voltage is applied on gates. However, as sizes of semiconductor devices become smaller and smaller, the source and drain regions are getting closer and closer, conductive channels are getting shorter and shorter, and short-channel effects are more and more obvious, which causes the devices to be unable to be truly disabled, and electric leakage is serious.

### SUMMARY

The present disclosure provides a semiconductor structure and a method for fabricating a semiconductor structure to improve performance of the semiconductor structure.

According to a first aspect of the present disclosure, there is provided a semiconductor structure, which includes:

a channel layer comprising a group III-V semiconductor and a group III-V semiconductor layer, the group III-V semiconductor and the group III-V semiconductor layer forming a heterojunction;

a gate structure positioned on the channel layer, the gate structure comprising a gallium oxide layer, a gate oxide layer, and a gate electrode stacked in sequence;

a source electrode positioned at an end of the heterojunction; and

a drain electrode positioned at other end of the heterojunction.

According to a second aspect of the present disclosure, there is provided a method for fabricating a semiconductor structure, including:

providing a substrate;

forming a channel layer on the substrate, the channel layer comprising a group III-V semiconductor and a group III-V semiconductor layer, the group III-V semiconductor and the group III-V semiconductor layer forming a heterojunction;

forming a gate structure on the channel layer, the gate structure comprising a gallium oxide layer, a gate oxide layer, and a gate electrode stacked in sequence; and

forming a source electrode and a drain electrode respectively at two ends of the heterojunction.

### BRIEF DESCRIPTION OF THE DRAWINGS

Various objectives, features and advantages of the present disclosure will become more apparent by considering the following detailed description of some embodiments of the present disclosure with reference to the accompanying drawings. The accompanying drawings are merely exemplary illustration of the present disclosure, and are not necessarily drawn to scale. The same reference numerals in the accompanying drawings always indicate the same or similar components. In the accompanying drawings:

FIG. 1 is a schematic flow chart showing a method for fabricating a semiconductor structure according to an exemplary embodiment;

FIG. 2 is a schematic structural diagram of a buffer layer formed by means of a method for fabricating a semiconductor structure according to an exemplary embodiment;

FIG. 3 is a schematic structural diagram of a gallium nitride layer formed by means of a method for fabricating a semiconductor structure according to an exemplary embodiment;

FIG. 4 is a schematic structural diagram of a trench formed by means of a method for fabricating a semiconductor structure according to an exemplary embodiment;

FIG. 5 is a schematic structural diagram of a group III-V semiconductor layer formed by means of a method for fabricating a semiconductor structure according to an exemplary embodiment;

FIG. 6 is a schematic structural diagram of a gallium oxide layer formed by means of a method for fabricating a semiconductor structure according to an exemplary embodiment;

FIG. 7 is a schematic structural diagram of a gate oxide layer formed by means of a method for fabricating a semiconductor structure according to an exemplary embodiment; and

FIG. 8 is a schematic structural diagram showing a semiconductor structure according to an exemplary embodiment.

Reference numerals in the accompanying drawings are as follows:

10—channel layer; 11—group III—V semiconductor; 111—trench; 112—mask layer; 12—group III—V semiconductor layer; 13—opening; 20—gate structure; 22—gallium oxide layer; 23—gate oxide layer; 24—gate electrode; 30—source electrode; 40—drain electrode; 50—substrate; 51—base; 52—nucleation layer; and 53—buffer layer.

### DETAILED DESCRIPTION

Typical embodiments embodying features and advantages of the present disclosure will be described in detail in the following specification. It is to be understood that the present disclosure may have various changes on different embodiments, which does not depart from the scope of the present disclosure, and the description and accompanying drawings therein in essence are used for illustrating but not intended for limiting the present disclosure.

In the following description of different exemplary embodiments of the present disclosure, it is made with reference to the accompanying drawings, which form a part of the present disclosure, and therein different exemplary structures, systems and steps that can implement various aspects of the present disclosure are shown by way of example. It should be understood that other solutions of components, structures, exemplary apparatuses, systems, and steps may be used, and structural and functional modifications may be made without departing from the scope of the present disclosure. Moreover, although the terms “above”, “between”, “within”, etc. may be used in this specification to describe different exemplary features and elements of the present disclosure, these terms are used herein for convenience only, such as directions of the examples in the accompanying drawings. Nothing in this specification should be understood as requiring a three-dimensional direction of the structure to fall within the scope of the present disclosure.

One embodiment of the present disclosure provides a method for fabricating a semiconductor structure. referring to FIG. 1, this method for fabricating a semiconductor structure includes following steps:

S101: providing a substrate;

S103: forming a channel layer 10 on the substrate 50, the channel layer 10 including a group III-V semiconductor 11 and a group III-V semiconductor layer 12, and the group III-V semiconductor 11 and the group III-V semiconductor layer 12 forming a heterojunction;

S105: forming a gate structure 20 on the channel layer 10, the gate structure 20 including a gallium oxide layer 22, a gate oxide layer 23, and a gate electrode 24 stacked in sequence; and

S107: forming a source electrode 30 and a drain electrode 40 at two ends of the heterojunction, respectively.

The method for fabricating a semiconductor structure according to one embodiment of the present disclosure is used for forming a semiconductor structure, wherein the semiconductor structure includes a channel layer 10, a gate structure 20, a source electrode 30, and a drain electrode 40. The heterojunction is formed by the group III-V semiconductor 11 and the group III-V semiconductor layer 12, such that a two-dimensional electron gas (2DEG) is formed at an interface, which becomes a natural channel carrier. Transmission of electrons is implemented under an action of an electric field, to form an electrical connection between the source electrode 30 and the drain electrode 40. The gallium oxide layer 22 is provided between the group III-V semiconductor layer 12 and the gate oxide layer 23, to prevent surface defects from being caused by a reaction between the gate oxide layer 23 and the group III-V semiconductor layer 12, to improve the performance of the semiconductor structure.

In some embodiments, the substrate 50 may include a silicon carbide substrate, a sapphire substrate, or a silicon substrate. Further, the substrate 50 may be formed of any suitable material, for example, at least one of silicon, monocrystal silicon, polycrystalline silicon, amorphous silicon, silicon germanium, monocrystal silicon germanium, polycrystalline silicon germanium, and carbon-doped silicon.

In some embodiments, the gate electrode 24 may be any suitable metal, for example, nickel, tungsten, gold, aluminum, titanium, titanium nitride, copper, and alloys thereof.

The source electrode 30 and the drain electrode 40 may be any suitable metal, for example, nickel, tungsten, gold, aluminum, titanium, titanium nitride, copper, and alloys thereof.

In some embodiments, the gate oxide layer 23 includes a high-k dielectric material layer, and the high-k dielectric material layer can further increase a physical thickness of a gate dielectric layer on a basis of maintaining the same equivalent oxide thickness (EOT), such that leakage current is effectively reduced, and thus it is more conducive to switching of a device.

Materials of the high-k dielectric material layer include, for example, hafnium oxide, silicon hafnium oxide, lanthanum oxide, lanthanum aluminum oxide, zirconium oxide, silicon zirconium oxide, tantalum oxide, silicon tantalum oxide, titanium oxide, barium strontium titanium oxide, barium titanium oxide, strontium titanium oxide, yttrium oxide, aluminum oxide, silicon oxide, lead scandium tantalum oxide, and lead zinc niobate.

In some embodiments, the group III-V semiconductor 11 and the group III-V semiconductor layer 12 form a heterojunction. That is, the group III-V semiconductor 11 and the group III-V semiconductor layer 12 may be any material structure that can form the 2DEG in the related art. For example, the heterojunction is a heterojunction formed by AlGaN and GaN, or the heterojunction is a heterojunction formed by AlN and GaN, etc.

In one embodiment, the group III-V semiconductor 11 includes gallium nitride. In some embodiments, the group III-V semiconductor layer 12 may include aluminum gallium nitride (AlGaN) or aluminum nitride.

In one embodiment, the gallium oxide layer 22 includes P-type doped ions. The group III-V semiconductor 11 and the group III-V semiconductor layer 12 form a heterojunction. That is, a two-dimensional electron gas (2DEG) may be formed at the interface between the group III-V semiconductor 11 and the group III-V semiconductor layer 12. As a conductive channel, the 2DEG has high electron mobility, and may be driven by a gate voltage such that electric current flows from the source region to the drain region. A heterojunction transistor constituted by this 2DEG channel is a normally-on device, and the 2DEG conductive channel still exists when no gate voltage is applied. Therefore, a P-type doped gallium oxide layer 22 is provided between the group III-V semiconductor layer 12 and the gate oxide layer 23, and depletion of the 2DEG is implemented by forming a PN junction, such that the transistor is disabled. The 2DEG serves as an N region of the PN junction, and the gallium oxide layer 22 including the P-type doped ions serves as a P region of the PN junction.

In one embodiment, the method for fabricating a semiconductor structure further includes: forming a trench 111 on the channel layer 10 before the gate structure 20 is formed on the channel layer 10, wherein the gate structure 20 is formed in the trench 111. That is, the buried gate structure 20 is formed.

In some embodiments, the gallium oxide layer 22, the gate oxide layer 23, and the gate electrode 24 may be sequentially formed in the trench 111, such that the gallium oxide layer 22, the gate oxide layer 23, and the gate electrode 24 completely fill the trench 111. The trench 111 is formed in the group III-V semiconductor layer 12.

In one embodiment, the channel layer 10 includes a gallium nitride layer and the group III-V semiconductor layer 12, wherein the gallium nitride layer is formed on the substrate 50. That is, the group III-V semiconductor 11 may be a gallium nitride layer, wherein the gallium nitride layer and the group III-V semiconductor layer 12 form the heterojunction. The group III-V semiconductor layer 12 may include aluminum gallium nitride (AlGaN) or aluminum nitride to form the heterojunction with the gallium nitride layer.

In some embodiments, the substrate 50 may only include a base 51, and the channel layer 10 is directly formed on the base 51. The base 51 may include a silicon carbide substrate, a sapphire substrate, or a silicon substrate. Further, the base 51 may be formed of any suitable material, for example, at least one of silicon, monocrystal silicon, polycrystalline silicon, amorphous silicon, silicon germanium, monocrystal silicon germanium, polycrystalline silicon germanium, and carbon-doped silicon.

In some embodiments, the substrate 50 may include the base 51 and a buffer structure, wherein the buffer structure is formed on the base 51, and the channel layer 10 is formed on the buffer structure. The buffer structure can allow the group III-V semiconductor 11 of the channel layer 10 and the substrate 50 to better form the interface, such that the channel layer 10 can achieve a desired device quality.

It is to be noted that the buffer structure may include any suitable group III-V semiconductor materials, and include III-N semiconductor materials in some cases.

In some embodiments, the buffer structure may only include a buffer layer 53, wherein the buffer layer 53 is formed on the base 51, and the channel layer 10 is formed on the buffer layer 53. The buffer layer 53 facilitates subsequently forming a high-quality gallium nitride layer in the channel layer 10, thereby avoiding quality problems caused by directly forming the gallium nitride layer on the base 51.

In some embodiments, the buffer layer 53 may include any suitable group III-V semiconductor materials. In some embodiments, the buffer layer 53 includes III-N group semiconductor materials. In this embodiment, the buffer layer 53 includes gallium nitride.

In some embodiments, the buffer structure may include a nucleation layer 52 and the buffer layer 53, wherein the nucleation layer 52 is formed on the base 51, the buffer layer 53 is formed on the nucleation layer 52, and the channel layer 10 is formed on the buffer layer 53. The nucleation layer 52 can improve growth conditions and/or prevent the channel layer from reacting with substrate materials in an undesired manner.

In some embodiments, the nucleation layer 52 may include any suitable group III-V semiconductor material or III-N group semiconductor material, such as an AlN layer or a low-temperature GaN layer. In this embodiment, the nucleation layer 52 includes aluminum nitride.

It is to be noted that the nucleation layer 52 and the buffer layer 53 may formed by means of processes such as molecular beam epitaxy (MBE) or metal-organic chemical vapor deposition (MOCVD).

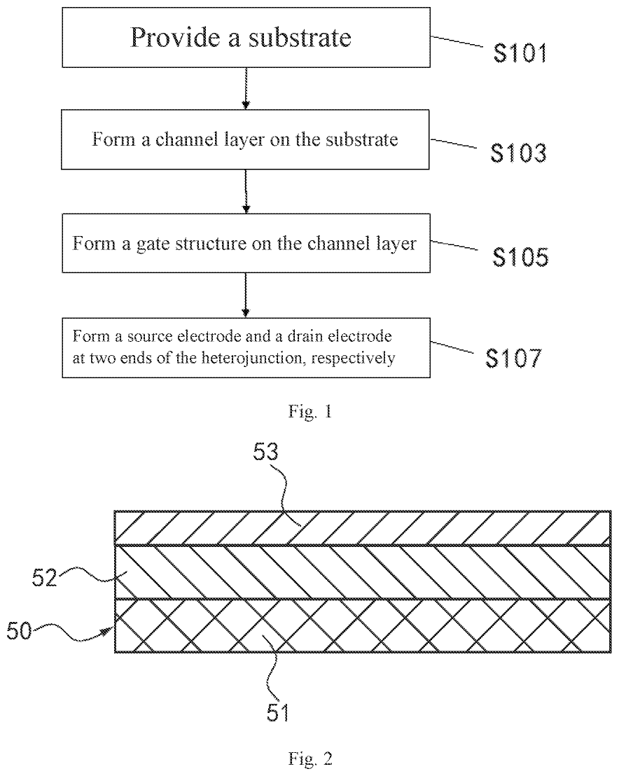

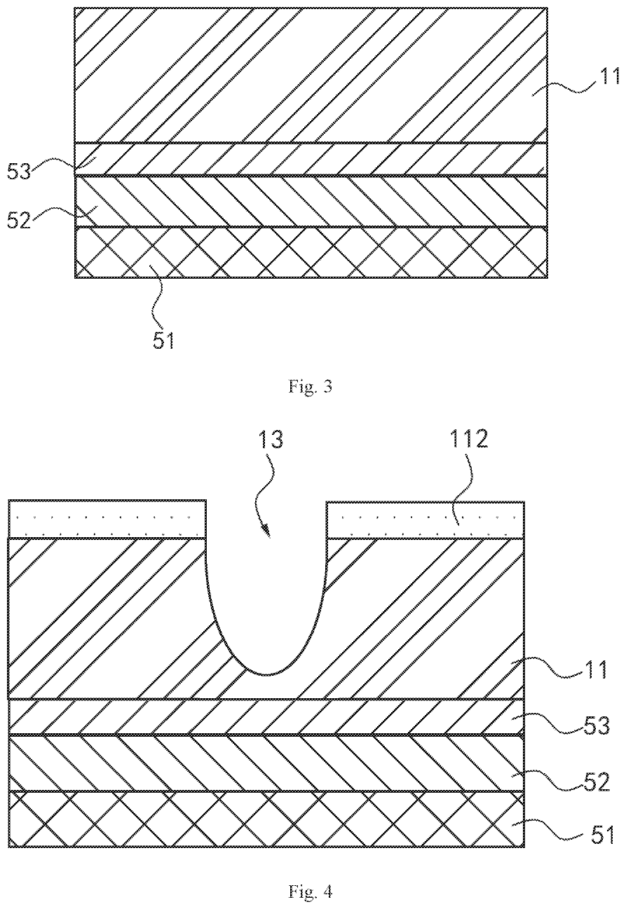

As shown in FIG. 2, the nucleation layer 52 and the buffer layer 53 are sequentially formed on the base 51. As shown in FIG. 3, a gallium nitride layer may be formed on the buffer layer 53 by means of MBE or MOCVD. That is, the group III-V semiconductor 11 is formed. A mask layer 112 is covered on the group III-V semiconductor 11, and a particular region is etched, such that an opening 13 as shown in FIG. 4 is formed. In some embodiments, the patterned mask layer 112 has a mask opening that exposes a surface of the group III-V semiconductor 11, wherein the mask opening defines a shape and a location of the gate structure 20. Next, the group III-V semiconductor 11 is etched based on the patterned mask layer 112 to form the opening 13 as shown in FIG. 4.

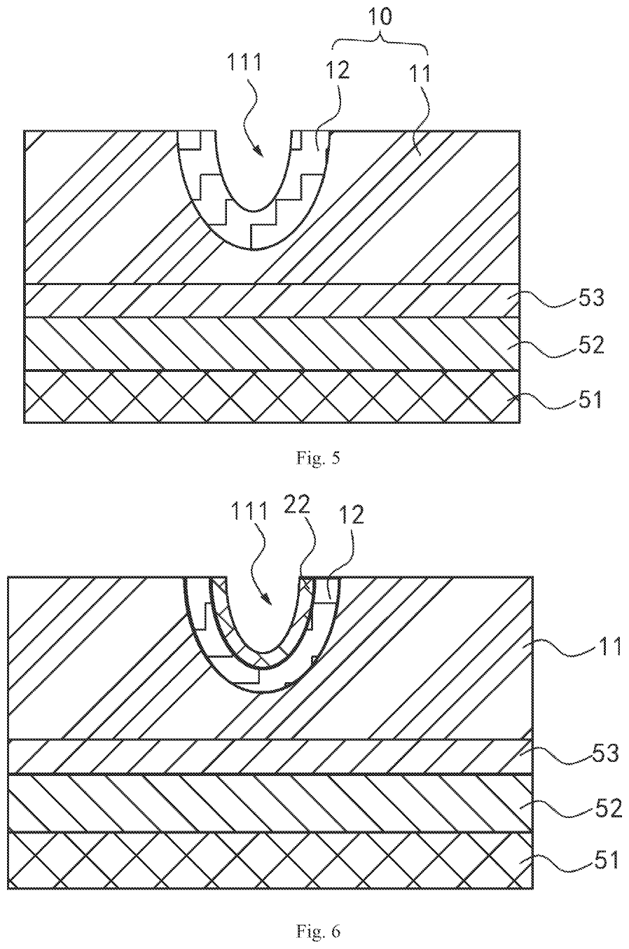

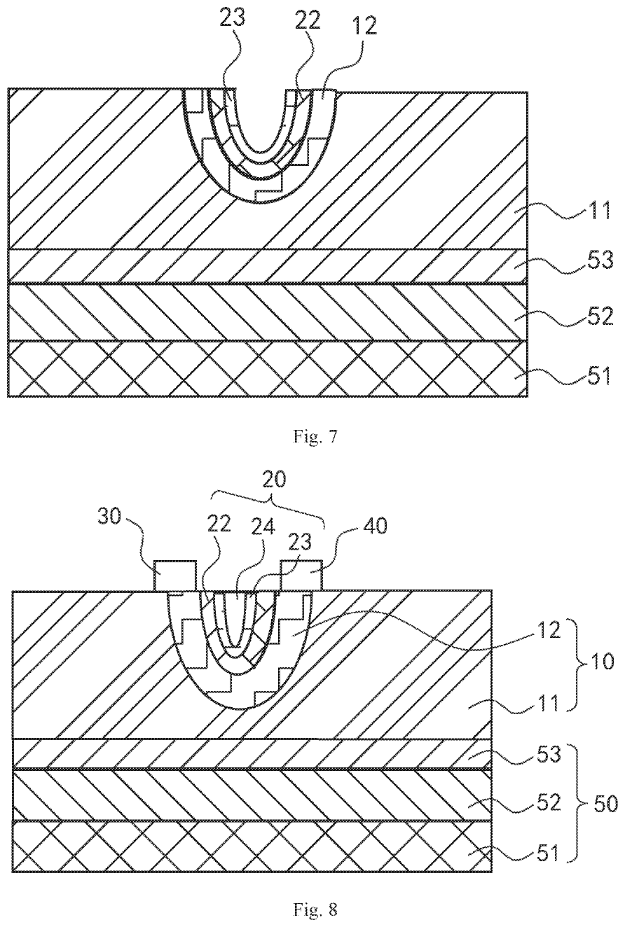

As shown in FIG. 5, the group III-V semiconductor layer 12 is formed on a sidewall of the opening 13. The group III-V semiconductor layer 12 may be formed by means of chemical vapor deposition (CVD), MBE, etc. That is, the group III-V semiconductor 11 and the group III-V semiconductor layer 12 constitute the channel layer 10. At this moment, the trench 111 is formed inside the group III-V semiconductor layer 12. Next, the gallium oxide layer 22 as shown in FIG. 6 is formed on a sidewall of the group III-V semiconductor layer 12 by means of MBE or MOCVD, etc. Next, the gate oxide layer 23 as shown in FIG. 7 is formed on a surface of the gallium oxide layer 22 by means of atomic layer deposition (ALD), etc. Finally, the gate electrode 24 as shown in FIG. 8 is formed in the gate oxide layer 23 by means of electron beam evaporation or the like, and the source electrode 30 and the drain electrode 40 are respectively formed at two ends of the heterojunction.

It is to be noted that order of formation of the source electrode 30, the drain electrode 40 and the gate oxide layer 23 is not limited.

One embodiment of the present disclosure provides a semiconductor structure. Referring to FIG. 8, the semiconductor structure includes: the channel layer 10 including the group III-V semiconductor 11 and the group III-V semiconductor layer 12, wherein the group III-V semiconductor 11 and the group III-V semiconductor layer 12 form the heterojunction; the gate structure 20 positioned on the channel layer 10, wherein the gate structure 20 includes the gallium oxide layer 22, the gate oxide layer 23, and the gate electrode 24 stacked in sequence; the source electrode 30 positioned at an end of the heterojunction; and the drain electrode 40 positioned at the other end of the heterojunction.

The semiconductor structure provided by one embodiment of the present disclosure includes the channel layer 10, the gate structure 20, the source electrode 30, and the drain electrode 40. The heterojunction is formed by the group III-V semiconductor 11 and the group III-V semiconductor layer 12, such that the 2DEG is formed at the interface, which becomes a natural channel carrier. Transmission of electrons is implemented under the action of the electric field, to form the electrical connection between the source electrode 30 and the drain electrode 40. The gallium oxide layer 22 is provided between the group III-V semiconductor layer 12 and the gate oxide layer 23, to prevent the surface defects from being caused by the reaction between the gate oxide layer 23 and the group III-V semiconductor layer 12, to improve the performance of the semiconductor structure.

It is to be noted that if the group III-V semiconductor layer 12 is in direct contact with the gate oxide layer 23, during a preparation process of the gate structure 20, after the gate oxide layer 23 is deposited, the gate oxide layer 23 is annealed at a high temperature, such that oxygen elements in the gate oxide layer 23 may diffuse and react with the group III-V semiconductor layer 12, and thus forming a group III-V oxide. If a quantity and a thickness of the oxide formed are uncontrollable, this may have a negative effect on surface quality of the gate oxide layer 23, and may cause more surface defects, such that the performance of the gate structure 20 is reduced. However, if the gallium oxide layer 22 is provided between the group III-V semiconductor layer 12 and the gate oxide layer 23, this is beneficial to eliminate such surface defects.

It is to be noted that the group III-V semiconductor 11 and the group III-V semiconductor layer 12 form the heterojunction. That is, the group III-V semiconductor 11 and the group III-V semiconductor layer 12 may be any material structure that can form the 2DEG in the related art. For example, the heterojunction is a heterojunction formed by AlGaN and GaN, or the heterojunction is a heterojunction formed by AlN and GaN, etc.

In some embodiments, AlGaN and GaN have different forbidden band widths. The forbidden band width of AlGaN is higher than that of GaN, such that there exists a conduction band differential between bottoms of conduction band of AlGaN and GaN. This conduction band differential and a large number of positive charges at the interface may bend an energy band on the bottom of conduction band, and the bent energy band may allow a two-dimensional potential well to be formed at the interface of the heterojunction. This two-dimensional potential well will confine polarization induced electrons. In the potential well, these electrons can only execute a two-dimensional motion along a plane parallel to an abrupt junction interface, so they are referred to as two-dimensional electron gas (2DEG).

In one embodiment, the group III-V semiconductor 11 includes gallium nitride. In some embodiments, the group III-V semiconductor layer 12 may include aluminum gallium nitride (AlGaN) or aluminum nitride.

In one embodiment, the gallium oxide layer 22 includes P-type doped ions. The group III-V semiconductor and the group III-V semiconductor layer 12 form the heterojunction. That is, the 2DEG may be formed at the interface between the group III-V semiconductor 11 and the group III-V semiconductor layer 12. As a conductive channel, the 2DEG has high electron mobility, and may be driven by a gate voltage such that electric current flows from the source region to the drain region. A heterojunction transistor constituted by this 2DEG channel is a normally-on device, and the 2DEG conductive channel still exists when no gate voltage is applied. Therefore, a P-type doped gallium oxide layer 22 is provided between the group III-V semiconductor layer 12 and the gate oxide layer 23, and depletion of the 2DEG is implemented by forming a PN junction, such that the transistor is disabled. The 2DEG serves as an N region of the PN junction, and the gallium oxide layer 22 including the P-type doped ions serves as a P region of the PN junction.

In some embodiments, the gate oxide layer 23 includes a high-k dielectric material layer, and the high-k dielectric material layer can further increase the physical thickness of the gate dielectric layer on the basis of maintaining the same equivalent oxide thickness (EOT), such that the leakage current is effectively reduced, and thus it is more conducive to switching of the device.

In some embodiments, materials of the high-k dielectric material layer include, for example, hafnium oxide, silicon hafnium oxide, lanthanum oxide, lanthanum aluminum oxide, zirconium oxide, silicon zirconium oxide, tantalum oxide, silicon tantalum oxide, titanium oxide, barium strontium titanium oxide, barium titanium oxide, strontium titanium oxide, yttrium oxide, aluminum oxide, silicon oxide, lead scandium tantalum oxide, and lead zinc niobate.

In one embodiment, as shown in FIG. 8, the gate structure 20 is positioned in the channel layer 10. In some embodiments, the trench 111 may be formed in the channel layer 10, such that the gate structure 20 is arranged in the trench 111 to form the buried gate structure 20.

Further, the source electrode 30 is positioned at one end of the heterojunction, the drain electrode 40 is positioned at the other end of the heterojunction, and both the source electrode 30 and the drain electrode 40 may be positioned on an upper surface of the channel layer 10. The source electrode 30 and the drain electrode 40 are in direct contact with a 2DEG channel.

In some embodiments, the gate structure 20 may be positioned on the upper surface of the channel layer 10.

In one embodiment, as shown in FIG. 8, the semiconductor structure also includes a substrate 50, wherein the channel layer 10 is positioned on the substrate 50. The channel layer 10 includes a gallium nitride layer positioned on the substrate 50, and the channel layer 10 and the group III-V semiconductor layer 12 form the heterojunction. That is, the group III-V semiconductor 11 may include a gallium nitride layer. The group III-V semiconductor layer 12 may include aluminum gallium nitride (AlGaN) or aluminum nitride to form the heterojunction with the gallium nitride layer.

In some embodiments, the substrate 50 may only include the base 51, and the channel layer 10 is directly positioned on the base 51. The base 51 may include a silicon carbide substrate, a sapphire substrate, or a silicon substrate. Further, the base 51 may be formed of any suitable material, for example, at least one of silicon, monocrystal silicon, polycrystalline silicon, amorphous silicon, silicon germanium, monocrystal silicon germanium, polycrystalline silicon germanium, and carbon-doped silicon.

In some embodiments, the substrate 50 may include the base 51 and a buffer structure, wherein the buffer structure is positioned on the base 51, and the channel layer 10 is positioned on the buffer structure. The buffer structure can allow the group III-V semiconductor 11 of the channel layer 10 and the substrate 50 to better form the interface, such that the channel layer 10 can achieve the desired device quality.

It is to be noted that the buffer structure may include any suitable group III-V semiconductor materials, and include III-N semiconductor materials in some cases.

In some embodiments, the buffer structure includes a buffer layer 53, which is positioned between the base 51 and the channel layer 10. The buffer layer 53 facilitates subsequently forming a gallium nitride layer, thereby avoiding quality problems caused by directly forming the gallium nitride layer on the base 51.

Further, a thickness of the buffer layer 53 is less than that of the gallium nitride layer, and the buffer layer 53 can better form the interface with the base 51, thereby avoiding the interface quality problems caused by directly forming the thicker gallium nitride layer on the base 51.

In some embodiments, the buffer layer 53 may include any suitable group III-V semiconductor materials. In some embodiments, the buffer layer 53 includes III-N group semiconductor materials. In this embodiment, the buffer layer 53 includes gallium nitride.

It is to be noted that when the base 51 is a group III-V semiconductor material substrate, the buffer structure may only include the buffer layer 53, which is directly formed on the base 51.

In some embodiments, the buffer layer 53 includes a group III-V semiconductor, the base 51 includes a non-group III-V semiconductor, and the buffer structure also includes the nucleation layer 52, which is positioned between the base 51 and the buffer layer 53. That is, when the group III-V semiconductor material is formed on a non-group III-V semiconductor material substrate (such as a germanium-silicon substrate or silicon substrate), the buffer structure includes the nucleation layer 52. The nucleation layer 52 can improve growth conditions and/or prevent the channel layer from reacting with substrate materials in an undesired manner.

In some embodiments, the nucleation layer 52 may include any suitable group III-V semiconductor material or III-N group semiconductor material, such as an AlN layer or a low-temperature GaN layer. In this embodiment, the nucleation layer 52 includes aluminum nitride.

In some embodiments, the nucleation layer 52 may have any suitable thickness, such as a thickness of 10 nm to 2 μm (e.g., 200 nm to 1 μm), or any other suitable thickness that will be apparent from the present disclosure. When the base 51 is the silicon substrate, the channel layer 10 is GaN, and the nucleation layer 52 is AlN. In this case, the buffer layer 53 may be GaN to release a stress during the formation of the channel region, thereby preventing the stress from having a negative effect on carrier mobility of the channel region.

It is to be noted that in one embodiment, the semiconductor structure may be obtained by the above-mentioned method for fabricating a semiconductor structure.

In the related technologies, a field-effect transistor utilizes doping to control ON or OFF of the device by controlling accumulation or inversion in the channel. The semiconductor structure of the present disclosure may take advantage of characteristics of the GaN/AlGaN material to form the 2DEG at the interface, which may become a natural channel carrier configured to implement the transmission of the electrons under the action of the electric field.

Furthermore, a P-type Ga2O3 is inserted in a periphery, and depletion of the 2DEG is implemented by forming a PN junction, such that the transistor is disabled. That is, a switching-controllable device is formed by means of the PN junction, and a device without the PN junction is a normally-on device. In addition, the introduction of Ga2O3 is beneficial to prevent the gate oxide layer 23 from reacting with the group III-V semiconductor layer 12.

The present disclosure is intended to cover any variations, uses, or adaptations of the present disclosure following the general principles thereof and including such departures from the present disclosure as come within known or customary practice in the art. It is intended that the specification and embodiments be considered as exemplary only, with a true scope and spirit of the present disclosure being indicated by the appended claims.

It is to be appreciated that the present disclosure is not limited to the exact construction that has been described above and illustrated in the accompanying drawings, and that various modifications and changes can be made without departing from the scope thereof. It is intended that the scope of the present disclosure only be limited by the appended claims.

What is claimed is:

1. A semiconductor structure, comprising:
a channel layer comprising a group III-V semiconductor and a group III-V semiconductor layer, the group III-V semiconductor and the group III-V semiconductor layer forming a heterojunction;
a gate structure positioned on the channel layer, the gate structure comprising a gallium oxide layer, a gate oxide layer, and a gate electrode stacked in sequence;
a source electrode positioned at an end of the heterojunction; and
a drain electrode positioned at other end of the heterojunction.

2. The semiconductor structure according to claim 1, wherein the group III-V semiconductor layer comprises aluminum gallium nitride (AlGaN).

3. The semiconductor structure according to claim 1, wherein the gallium oxide layer comprises a P-type doped ion.

4. The semiconductor structure according to claim 1, wherein the gate oxide layer comprises a high-k dielectric material layer.

5. The semiconductor structure according to claim 1, wherein the gate structure is positioned in the channel layer.

6. The semiconductor structure according to claim 1, wherein the semiconductor structure further comprises a substrate, the channel layer being positioned on the substrate, the channel layer comprising a gallium nitride layer, the gallium nitride layer being positioned on the substrate and forming the heterojunction together with the group III-V semiconductor layer.

7. The semiconductor structure according to claim 6, wherein the substrate comprises:
a base; and
a buffer structure positioned on the base, the channel layer being positioned on the buffer structure.

8. The semiconductor structure according to claim 7, wherein the buffer structure comprises:
a buffer layer positioned between the base and the channel layer.

9. The semiconductor structure according to claim 8, wherein the buffer layer comprises a group III-V semiconductor, the base comprising a non-group III-V semiconductor, the buffer structure further comprising:
a nucleation layer positioned between the base and the buffer layer.

10. The semiconductor structure according to claim 9, wherein the buffer layer comprises gallium nitride, the nucleation layer comprising aluminum nitride.

11. The semiconductor structure according to claim 9, wherein a thickness of the nucleation layer is 10 nm to 2 μm.

12. The semiconductor structure according to claim 8, wherein a thickness of the buffer layer is less than that of the gallium nitride layer.

13. The semiconductor structure according to claim 7, wherein the base is a group III-V semiconductor material substrate, the buffer structure only comprising a buffer layer directly formed on the base.

14. The semiconductor structure according to claim 6, wherein the substrate only comprises a base, the channel layer being directly positioned on the base.

15. The semiconductor structure according to claim 1, wherein the source electrode and the drain electrode are both positioned on an upper surface of the channel layer.

16. A method for fabricating a semiconductor structure, comprising:
providing a substrate;
forming a channel layer on the substrate, the channel layer comprising a group III-V semiconductor and a group III-V semiconductor layer, the group III-V semiconductor and the group III-V semiconductor layer forming a heterojunction;
forming a gate structure on the channel layer, the gate structure comprising a gallium oxide layer, a gate oxide layer, and a gate electrode stacked in sequence; and
forming a source electrode and a drain electrode respectively at two ends of the heterojunction.

17. The method for fabricating a semiconductor structure according to claim 16, further comprising:
before forming a gate structure on the channel layer,
forming a trench on the channel layer;
wherein the gate structure is formed in the trench.

18. The method for fabricating a semiconductor structure according to claim 16, wherein the substrate comprises a base, a nucleation layer, and a buffer layer, the nucleation layer being formed on the base, the buffer layer being formed on the nucleation layer, the channel layer being formed on the buffer layer.

19. The method for fabricating a semiconductor structure according to claim 18, wherein the channel layer comprises a heterojunction formed by a gallium nitride layer and aluminum gallium nitride (AlGaN), the buffer layer comprising gallium nitride, the nucleation layer comprising aluminum nitride.

20. The method for fabricating a semiconductor structure according to claim 16, wherein the gallium oxide layer comprises a P-type doped ion.
